(19) United States
(12) Patent Application Publication
(10) Pub. No.: US 2018/0363130 A1
(43) Pub. Date: Dec. 20, 2018

(54) FILM FORMING APPARATUS

(71) Applicant: Applied Materials, Inc., Santa Clara, CA (US)

(72) Inventors: Andreas SAUER, Großostheim (DE); Annabelle HOFMANN, Stockstadt (DE)

(21) Appl. No.: 16/062,072

(22) PCT Filed: Dec. 21, 2015
(86) PCT No.: PCT/EP2015/080841

§ 371 Date: Jun. 13, 2018

(51) Int. Cl. C23C 14/56; C23C 16/54

(52) U.S. Cl. CPC C23C 14/562; C23C 16/545

(57) ABSTRACT

An apparatus for processing a thin film on a substrate is described. The apparatus includes a vacuum chamber comprising a housing, a rear wall and a removable closing plate; a processing drum being arranged between the rear wall and the removable closing plate inside the vacuum chamber, the processing drum being at least partially surrounded by a processing region; a first process separating wall portion attached to the removable closing plate; a second process separating wall portion attached to the housing or the rear wall; wherein in a closed position of the removable closing plate, the first process separating wall portion and the second process separating wall portion jointly provide a process separating wall dividing the processing region into adjacent processing sections.

### TECHNICAL FIELD

Embodiments of the present disclosure relate to thin-film processing apparatuses, particularly to deposition systems, and more particularly to roll-to-roll (R2R) deposition systems and methods for the maintenance thereof. Embodiments of the present disclosure particularly relate to gas separation in roll-to-roll deposition systems and methods for providing maintenance access thereto, specifically to apparatuses for coating a thin film on a flexible substrate and methods for providing a gas tight process separating wall between neighboring processing sections of a deposition apparatus.

### BACKGROUND

Processing of flexible substrates, such as plastic films or foils, is in high demand in the packaging industry, semiconductor industries, solar protecting window film industries, and other industries. Processing may comprise coating of a flexible substrate with a material, such as a metal, in particular silver, aluminum, titanium, niobium, or zinc and dielectric compounds thereof, such as e.g. aluminum doped zinc oxide. Systems performing this task usually include a processing drum, e.g., a cylindrical roller, coupled to a processing system for transporting the substrate, and on which at least a portion of the substrate is processed. Roll-to-roll deposition systems can provide a high throughput system.

Typically, an evaporation process, such as a thermal evaporation process, can be utilized for depositing thin layers of metals which can be metallized onto flexible substrates. However, roll-to-roll deposition systems are also experiencing a strong increase in demand in the display industry and the photovoltaic (PV) industry. For example, touch panel elements, flexible displays, optical filters, and flexible PV modules result in an increasing demand of depositing suitable layers or layer stacks in roll-to-roll coaters, particularly with low manufacturing costs. However, such devices typically have several layers, which are often manufactured with PVD processes such as sputtering processes or with CVD processes, such as PECVD processes. Roll-to-roll deposition systems for such sophisticated applications comprise several processing sections in adjacent compartments.

Over the years, layers in roll-to-roll deposition systems have evolved into multiple layers with each layer serving a different function. Depositing the multiple layers onto a flexible substrate may be performed in multiple processing sections of a roll-to-roll deposition system. A high uptime and a reduced downtime of the roll-to-roll deposition system reduce production costs. The total cost of ownership can further be reduced with a high quality level of the deposited layers or layer stacks. Therefore, it is a matter of economic concern to provide an efficient method and apparatus for processing flexible substrates which ensure a high deposition quality and a minimized production downtime, e.g. for maintenance purpose.

### SUMMARY

In light of the above, an apparatus for processing a thin film on a substrate, particularly an apparatus for processing flexible substrates, and a method for providing a gas tight process separating wall between adjacent processing sections in a vacuum chamber are provided. Further aspects, advantages, and features disclosure are apparent from the dependent claims, the description and the accompanying drawings.

According to one embodiment, an apparatus for processing a thin film on a substrate is provided. The apparatus includes a vacuum chamber comprising a housing, a rear wall and a removable closing plate, a processing drum being arranged between the rear wall and the removable closing plate inside the vacuum chamber, the processing drum being at least partially surrounded by a processing region, a first process separating wall portion attached to the removable closing plate, and a second process separating wall portion attached to the housing or the rear wall, wherein in a closed position of the removable closing plate, the first process separating wall portion and the second process separating wall portion jointly provide a process separating wall dividing the processing region into adjacent processing sections.

According to another embodiment, an apparatus for processing a thin film on a substrate is provided. The apparatus includes a vacuum chamber comprising a housing, a rear wall and a removable closing plate, a processing drum being arranged between the rear wall and the removable closing plate inside the vacuum chamber, the processing drum being at least partially surrounded by a processing region, one or more first process separating wall portions attached to the removable closing plate, one or more second process separating wall portions attached to the housing or the rear wall, and at least one processing unit attached to the removable closing plate, wherein two neighboring first process separating wall portions are mechanically connected with a reinforcing element, and wherein the one or more first process separating wall portions and the one or more second process separating wall portions jointly provide one or more process separating walls dividing the processing region into at least two adjacent processing sections.

According to a yet further embodiment, a method for providing a gas tight process separating wall between adjacent processing sections in a vacuum chamber is provided. The method includes moving a first process separating wall portion into a vacuum chamber by closing the vacuum chamber with a removable closing plate, and activating a gas tight seal between the first process separating wall portion and a second process separating wall portion.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG.1 shows a schematic side view of a roll-to-roll deposition apparatus for depositing thin films and having a gas separating wall according to embodiments described herein;

FIGS. 2A and 2B show cross-sections of a process separating wall of a roll-to-roll deposition apparatus according to embodiments described herein;

FIGS. 3A and 3B show schematic 3D views of a closing plate for a roll-to-roll deposition apparatus according to embodiments described herein;

FIG. 4 shows a 3D view of a processing chamber and a processing drum according to embodiments described herein;

FIG. 5 shows a flow chart illustrating a method for providing a gas tight process separating wall between adjacent processing sections in a vacuum chamber according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

It is noted here that a flexible substrate or web as used within the embodiments described herein can typically be characterized in that a flexible substrate is bendable. The term “web” may be synonymously used with the term “strip”, the term “tape”, or the term “flexible substrate”. For example, the web, as described in embodiments herein, may be a foil or another flexible substrate. However, as described in more detail below, the benefits of embodiments described herein may also be provided for non-flexible substrates or carriers of other inline-deposition systems. Yet, it is understood that particular benefit can be utilized for flexible substrates and applications for manufacturing devices on flexible substrates.

A roll-to-roll deposition apparatus can include an unwinding chamber, a processing chamber, and/or a re-winding chamber. In some roll-to-roll deposition apparatuses, unwinding and re-winding of the flexible substrate can be performed in a common winding chamber. The processing chamber can include a substrate transportation roller or a substrate transportation drum. The substrate transportation roller or drum can act as a support for a flexible substrate. The flexible substrate can be moved through a processing region by the substrate support, for example a processing drum. The processing drum can be a drum, a cylinder or a roller, such as a coating roller or a coating drum. The processing region can be arranged around at least a portion of the processing drum. In the processing region, different processes can be carried out. A process can be carried out in the interior of a compartment. Different processes can be carried out in different adjacent compartments. A compartment can be a part of the processing region. A compartment can be separated from an adjacent compartment or further areas of the processing chamber or the deposition apparatus by process separating walls. A compartment can include parts of the walls of the processing chamber housing and process separating walls. The walls of a compartment define a volume of a processing section. For carrying out a process, one or more processing units can be provided in a processing section or compartment.

In the compartments, different processes and/or different processing techniques can be installed. For the different processes and/or different processing techniques, different processing gases may be used. The combination of several CVD and/or PVD sources working with different gas mixtures and/or different working pressures faces the need of an improved process gas separation to avoid cross contamination effects in the subsequent processes and to ensure the long term process stability. Also, the improved process gas separation level provides the technical condition for depositing well defined layer material compounds. The deposition of complex thin film layer structures can be performed in subsequent, different processing sections or compartments of roll-to roll coaters. As explained above, different compartments can be separated by processing separating walls. A portion of a processing separating wall may be a wall of a gas separation unit. The gas separation unit may be included in the processing separating wall. In some roll-to-roll coating machines, the compartments, e.g. sputter compartments, can be separated by a slit or gap which follows the curvature of the processing drum. The gas separation is dependent on the distance between the processing drum and the walls of the gas separation unit. The distance between the processing drum and the walls of the gas separation unit defines a width of the slit or gap. In order to provide a constant gas separation factor over the coating width, the gas separation unit is arranged in a constant distance over the width of the processing drum. For a constant distance between the gas separation unit and the processing drum, the walls of the gas separation unit may be arranged parallel to the axis of rotation of the processing drum. Further, the gas separation is dependent on the length of the slit or gap in direction of the gas flow. The direction of the gas flow may correspond to the direction of the substrate transport.

For maintenance purposes, an operator needs access to several components inside the housing of the roll-to-roll deposition apparatus. For maintenance access, components of the roll-to-roll deposition apparatus can be removed from the housing. Such components can be processing units, e.g. evaporator arrangements or sputtering cathodes.

Additionally, also portions of a winding system may be removed. The winding system can transport the flexible substrate from an unwinding roller through a processing region to a winding-up roller. The winding system may further include deflection rollers and/or guiding rollers.

In the processing region, the flexible substrate is supported by a substrate support, for example a processing drum. The rollers of the winding system and the processing drum may be arranged in a roller frame.

It may be beneficial to keep the winding system and the processing drum stationary in the roll-to-roll deposition apparatus. Keeping the winding system and processing drum stationary in the roll-to-roll deposition apparatus allows for having the flexible substrate within the system during maintenance. The winding system and the processing drum are adjusted to provide a directional stability or on-center feel of the flexible substrate. It may further be beneficial to keep the walls or at least portions of the walls of the gas separation unit stationary in the roll-to-roll deposition apparatus. According to embodiments described herein, an apparatus for processing a thin film on a substrate is provided. The apparatus includes a vacuum chamber comprising a housing, a rear wall and a removable closing plate, a processing drum being arranged between the rear wall and the removable closing plate inside the vacuum chamber, the processing drum being at least partially surrounded by a processing region, a first process separating wall portion attached to the removable closing plate, and a second process separating wall portion attached to the housing or the rear wall; wherein in a closed position of the removable closing plate, the first process separating wall portion and the second process separating wall portion jointly provide a process separating wall dividing the processing region into adjacent processing sections.

According to some embodiments of the disclosure described herein, a roll-to-roll deposition apparatus can be provided which includes a stationary winding system, a stationary processing drum, and a stationary gas separation unit and further provides space for access to the housing of the roll-to-roll deposition apparatus. According to embodiments described herein, a relative motion of the processing roller and the walls or portions of the walls of the gas separation unit is can be avoided or reduced. Such relative motion can cause a contact of the walls of the gas separation unit and the processing drum which is spaced at close distance to the gas separation unit. A contact can lead to scratches on the surface of the processing drum which is manufactured under observation of strong tolerances. Scratches on the processing drum result in an expensive and major repair and stoppage in production.

According to embodiments as described herein, process separating walls, e.g. two-part process separating walls give the beneficial effect to provide space for maintenance access to the compartments. The two-part design renders a process separating wall divisible. A process separating wall may comprise a first process separating wall portion and a second process separating wall portion. The new design of the process separating wall renders it possible to keep the adjustment of a wall of the gas separation unit unmodified. According to another embodiment, the design of the vessel or housing of the roll-to-roll coater further enlarges the space for an operator to access the compartments for maintenance. The rectangular cross-section shape of the vacuum chamber or housing of the roll-to-roll coater provides space for accessing the processing sections or compartments. The first process separating wall portion of a process separating wall can be removed out of the vacuum chamber or housing of the roll-to-roll coater. The second process separating wall portion of a process separating wall remains in the vacuum chamber or housing of the roll-to-roll coater. The second process separating wall portion of a process separating wall remains in narrow distance facing the processing drum. The narrow distance defines the gap for the gas separation.

According to embodiments as described herein, the compartment separation can be achieved by a mechanical structure attached to a flange plate or closing plate. The mechanical structure can comprise several first process separating wall portions of the process separating walls. The first process separating wall portion can be attached to the flange plate or closing plate. The first process separating wall portion can be a part of the mechanical structure. For maintenance, the closing plate can be removed from the processing chamber or housing of the roll-to-roll deposition apparatus. The closing plate can be removed from the processing chamber into an open position. By removing the closing plate from the processing chamber, the first process separating wall portions can be removed from the processing chamber or the housing of the roll-to-roll deposition apparatus. The second process separating wall portion can be the second part of the process separating wall. The second process separating wall portion remains in the processing chamber or housing of the roll-to-roll deposition apparatus during maintenance.

By closing the roll-to-roll deposition apparatus with the flange plate or closing plate, the first process separating wall portions can be moved inside the housing of the processing chamber. The closing plate may be brought into a closed position. In the closed position, the closing plate may seal the vacuum chamber of the roll-to-roll deposition apparatus in a vacuum tight manner. The first process separating wall portion of a process separating wall can be provided in a blade-like shape. For example, the blade-like shape may be basically rectangular. At least one side of the basically rectangular shape may be attached to the closing plate.

According to an embodiment described herein, at least a further side of the first process separating wall portion can be provided with a seal, particularly two further sides of the first process separating wall portion can be provided with seals, more particularly three further sides of the first process separating wall portion can be provided with seals. The seal attached to three sides of the first process separating wall portion may be regarded as an at least partially circumferential seal. The seal attached to the further side may face the vessel housing wall of the roll-to-roll deposition apparatus. The seal attached to a second further side may face the rear wall of the vessel housing of the roll-to-roll deposition apparatus. The seal attached to a third further side of the first process separating wall portion may face the second process separating wall portion. The second process separating wall portion may be provided with a static rib. The seal attached to the third side of the first process separating wall portion may face the static rib of the second process separating wall portion. The static ribs can be parts of the second process separating wall portions.

The seal can be realized as inflatable gasket. The gasket can be inflated with air, pressurized air, or a processing gas. By pressurizing the inflatable gasket, the remaining gaps between the first and second portions of the process separating walls and/or the housing walls of the vessel can be closed in a gas tight manner. In the pressurized status, a basically gas tight separation of the several adjacent processing sections can be achieved. The sealing can be performed along the wall of the vacuum chamber. The sealing can further be performed along static ribs fixed in the processing region. According to embodiments described herein, coating widths more than 1600 mm can be realized, even coating widths of more than 2000 mm or even more than 3000 mm can be realized. Maintenance access is possible from inside the processing chamber. An operator can enter the processing chamber more easily, since the first process separation wall portion is removed upon opening the chamber. Further, the second process separation wall portion being stationary allows for having a small gap with respect to the processing drum without risking damage to the processing drum.

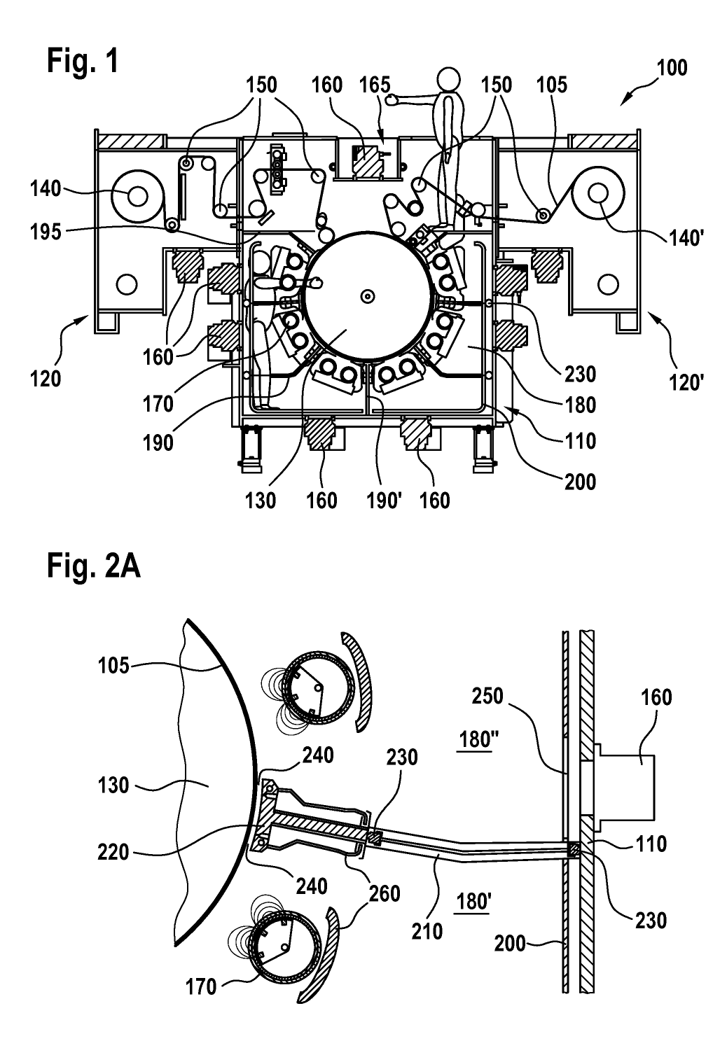

FIG. 1 shows an apparatus 100 for processing a thin film on a substrate. Apparatus 100 can be a vacuum processing apparatus, particularly a vacuum deposition apparatus, more particularly a roll-to-roll vacuum deposition apparatus. The deposition apparatus includes a processing chamber 110. Processing chamber 110 can be a vacuum chamber. Various vacuum processing techniques, and particularly vacuum deposition techniques, can be used to process the substrate or to deposit a thin-film on the substrate. As shown in FIG. 1, the apparatus 100 is a roll-to-roll deposition apparatus, wherein a flexible substrate 105 being guided and processed. However, according to some embodiments, which can be combined with other embodiments described herein, the aspects, details, and features of divisible process separation walls, which are described herein, can also be applied for other deposition apparatuses, wherein a glass substrate, a wafer, or another substrate, which can also be non-flexible, or which is provided in a non-flexible carrier, is processed.

As shown in FIG. 1, particularly for roll-to-roll deposition apparatuses, the substrate support in processing chamber 110 can be a processing drum 130. The flexible substrate 105 can be guided from an unwinding roller 140 over several guide rollers 150 into the processing chamber 110. Unwinding roller 140 can be arranged in unwinding chamber 120. The flexible substrate can be directed by several rollers to a substrate supporting processing drum 130 configured for supporting the substrate during processing and/or deposition. From the processing drum 130, the flexible substrate 105 can be guided over several guide rollers 150 to a re-winding roller 140′ arranged in re-winding chamber 120′. The winding system for transporting the flexible substrate through the roll-to-roll deposition apparatus includes several rollers e.g. unwinding roller 140, re-winding roller 140′, processing drum 130, spreader roller, guide rollers 150 and/or deflection rollers. The rollers and the processing drum of the winding system are arranged horizontally. For providing a directional stability or on-center feel of the flexible substrate through apparatus 100, the rollers can be adjusted parallel to each other. Unwinding chamber 120 and re-winding chamber 120′ can be laterally attached to processing chamber 110 such that the deposition apparatus has a flat top wall. Attaching the winding chambers laterally instead of above the processing region, prevent debris particles produced therein from falling down into the processing chamber 110. Further, the laterally attached winding chambers reduce the total height of apparatus 100. Reducing the total height of apparatus 100 provides a reduced working height for an operator. The flat top wall provides the operator safe access to the winding area being arranged in processing chamber 110 above processing drum 130.

According to an embodiment, the flat top wall further includes a recess 165. The recess in the top wall can be used for avoiding components to protrude greatly from the top wall. For example, sensitive components like vacuum gauges or other devices can be arranged in recess 165. Further, at least one vacuum pump 160 for evacuating the upper part of processing chamber 110 can be arranged in the recess. Any machine components protruding from the flat top wall can be a safety hazard for an operator moving or working upon the flat top wall. Further vacuum pumps 160 of the deposition apparatus can be arranged such that the vacuum pumps are located at lower parts of the housing. According to another embodiment, vacuum pumps 160 can be arranged in a hanging position at bottom sides of unwinding chamber 120 and re-winding chamber 120′ and/or processing chamber 110. This underneath position further keeps the flat top wall free of vacuum pumps. The underneath position of vacuum pumps reduces the danger of damaging the pumps since the pumps do not protrude laterally from the apparatus 100 into a service area. Via the service area, an operator can have access to the deposition apparatus.

For guiding the flexible substrate 105 from the unwinding chamber 120 into processing chamber 110 and further therefrom into re-winding chamber 120′, the respective chamber walls are provided with transition slits. The slits can be closed in a vacuum tight manner by gate valves which are not shown explicitly in FIG. 1. For maintenance purposes of the unwinding chamber 120 and/or the re-winding chamber 120′, the gate valves can be closed in a vacuum tight manner. The winding chambers can be vented while the processing chamber 110 can be kept under vacuum conditions. The flexible substrate 105 can be clamped in the gate valves and remain in the processing chamber 110. Ends of the flexible substrate can extend into the unwinding and/or re-winding chamber. After maintenance of the unwinding and/or re-winding chamber, new bales or empty winding shafts can be attached to the remaining flexible substrate which ends in the unwinding and/or re-winding chamber.

The embodiment depicted in FIG. 1 includes twelve processing units 170 arranged in six compartments. Each compartment defines a processing section 180. It is to be understood that the numbers of processing units and compartments as mentioned are only exemplarily. For example, the deposition apparatus can include eight or ten compartments. According to another embodiment, the deposition apparatus can include two or four compartments. Yet, it is to be understood that according to yet further embodiments, which can be combined with other embodiments described herein, one or more processing units 170 can be provided in a compartment. The number of processing units in different compartments can be identical. The number of processing units in different compartments can be different. The number of processing units in different compartments can be adapted to the intended process. One or more processing units are provided in a compartment for carrying out a process in a processing section 180, wherein the substrate being supported by the processing roller is processed. The processing sections can be separated from adjacent processing sections or further areas in processing chamber 110 by process separating walls 190.

According to embodiments described herein, the different processing sections 180 typically are separated from each other by process separating walls 190, 190′. The process separating walls 190, 190′ prevent gas of one processing section from entering a neighboring area, such as a neighboring processing section. As described more detailed below, a process separating wall 190 can include a first process separating wall portion and a second process separating wall portion. The first process separating wall portion is attached to a removable closing plate. The second process separating wall portion is attached to the housing or the rear wall of apparatus 100. The first process separating wall portions can be provided with a seal 230. In FIG. 1, only the seals facing the housing walls of the deposition apparatus are depicted.

The last process separating wall 195 upstream the processing region and/or the last process separating wall 195 downstream the processing region can be provided as single pieces rigidly attached to the housing and/or to the rear wall or can be a part of the housing of vacuum processing chamber 110. The rigidly attached last process separating wall 195 provided as single piece provides the possibility for operators to perform maintenance in a winding section of processing chamber 110. The winding section of processing chamber 110 can be arranged in a section above the processing region. According to an embodiment, the rigidly attached last process separating walls 195 can be arranged above processing drum 130.

According to a further embodiment which can be combined with other embodiments, the first process separating wall portion and a further first process separating wall portion can be mechanically connected with a reinforcing element 200. The further first process separating wall portion can be a neighboring first process separating wall portion. The reinforcing elements can be attached to two or more first process separating wall portions. The first process separating wall portions can be mechanically connected with a reinforcing element 200. As described more detailed below, the structure comprising first process separating wall portions and reinforcing elements can be attached to a removable closing plate of apparatus 100. In an open position of the removable closing plate, the first process separating wall portions and reinforcing elements can be positioned outside the vacuum chamber of apparatus 100. The removable closing plate 270 is not shown in FIG. 1. The reinforcing elements can comprise apertures which provide evacuation openings for vacuum pumps 160. The vacuum pumps 160 can be arranged behind the apertures for evacuating the compartments or processing sections 180. The space or volume between the vertical sides or shanks of reinforcing elements 200 can comprise a processing drum 130, compartments or processing sections 180, processing units 170, and/or first and second process separating wall portions.

According to an embodiment which can be combined with other embodiments described herein, the process separating wall 190′ underneath the processing drum 130 can be rigidly attached to the housing wall or the rear wall of deposition apparatus 100. According to this embodiment, the process separating wall 190′ is provided as a single piece rigidly attached to the housing and/or to the rear wall.

According to the embodiment shown in FIG. 1, the reinforcing element 200 can have an L-shaped cross-section. Two L-shaped reinforcing elements 200 can face each other with the horizontal sides or shanks The vertical sides of the L-shaped reinforcing elements are turned outwardly facing the lateral walls of processing chamber 110. The L-shaped reinforcing elements can be attached to the closing plate such that the L-shaped reinforcing elements are arranged on both sides of the process separating wall 190′ which is provided underneath the processing drum 130. Both horizontal sides or shanks of the L-shaped reinforcing elements can be arranged parallel to the process separating wall 190′. The ends of the horizontal side or shank of the L-shaped reinforcing elements can be arranged distant to the process separating wall 190′. The L-shaped reinforcing elements can be rigidly attached to a closing plate or mechanically connected with a closing plate (not shown in FIG. 1). The L-shaped reinforcing elements can be rigidly attached to the first process separating wall portions. The L-shaped reinforcing elements attached to first process separating wall portions can together be attached to a closing plate or closing flange (not shown in FIG. 1). The L-shaped reinforcing elements and the first process separating wall portions can be combined in a structure. The structure can be attached to the closing plate as cantilever construction.

It is to be understood that the reinforcing element 200 is not restricted to an L-shaped cross-section. According to another embodiment, the reinforcing element 200 can have a cross-section of e.g. a rectangular U. The rectangular U-shaped reinforcing element can be rigidly attached to the closing plate. The rectangular U-shaped reinforcing element can further be rigidly attached to the first process separating wall portions. According to this embodiment, the process separating wall 190′ comprises first and second process separating wall portions. The first process separating wall portion of process separating wall 190′ can be attached to the bottom part of the rectangular U-shaped reinforcing element. According to yet another embodiment which is described more detailed below, the reinforcing element 200 can be provided as a plate. This plate-like reinforcing element can be rigidly attached to two neighboring first process separating wall portions. The plate-like reinforcing element can be arranged such that the plate-like reinforcing element connects two neighboring first process separating wall portions. The plate-like reinforcing element can comprise apertures for providing evacuation openings for vacuum pumps 160. The vacuum pumps 160 can be arranged behind these apertures for evacuating the compartments or processing sections 180. The U-shaped or the plate-like reinforcing element and the first process separating wall portions can be combined in a structure. The structure can be attached to the closing plate as cantilever construction.

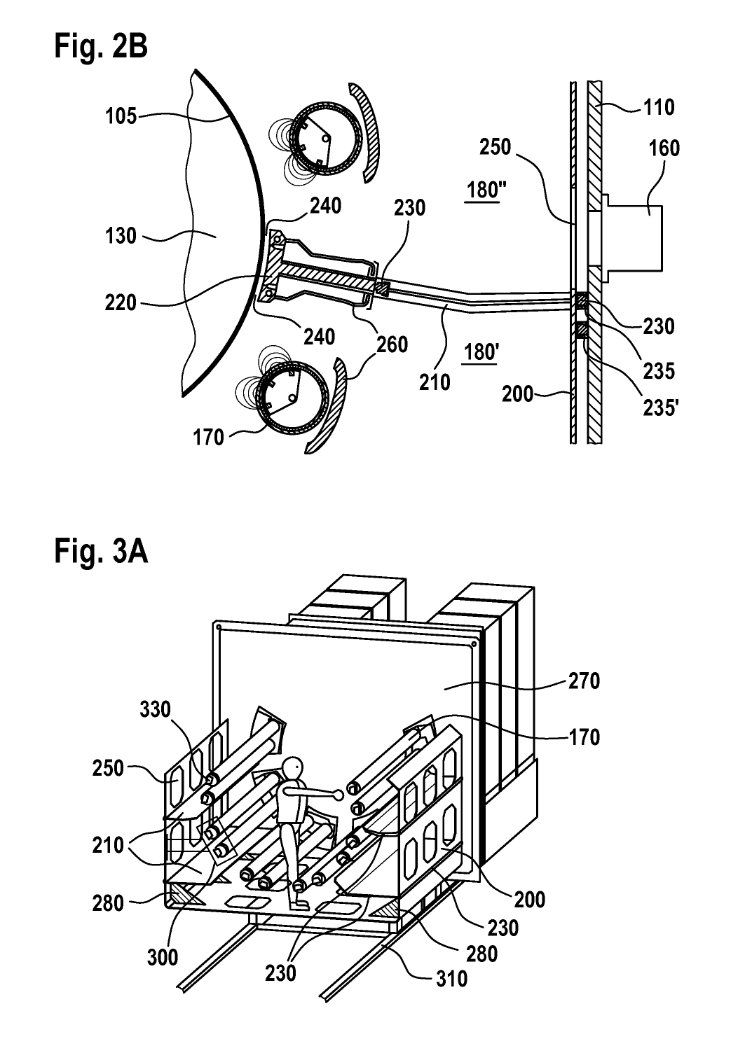

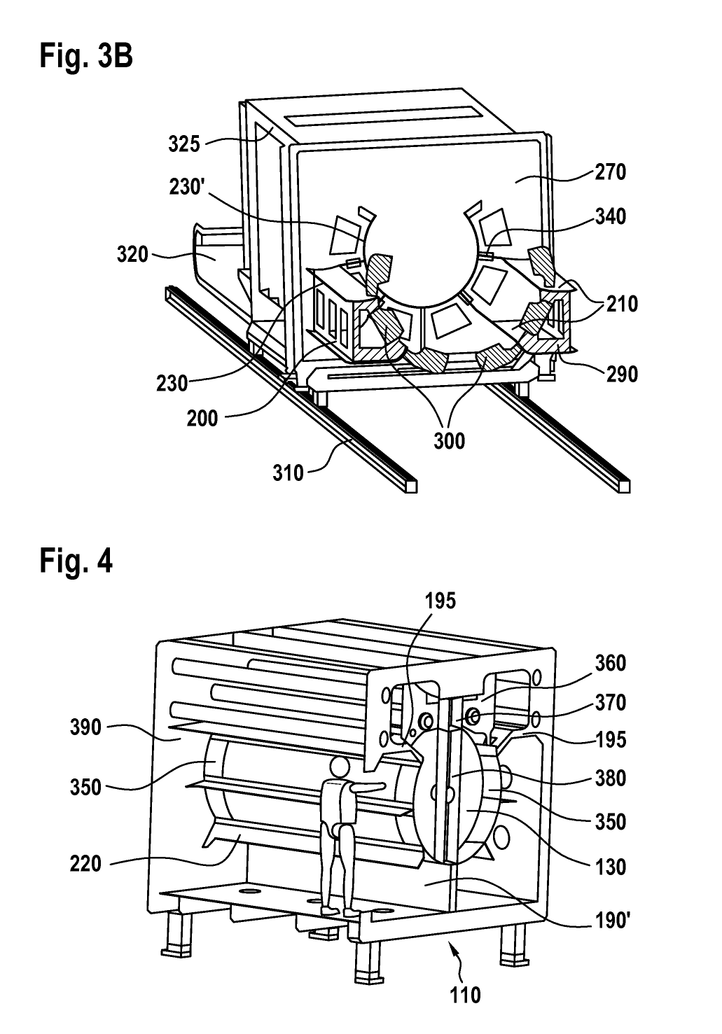

FIGS. 2A and 2B show a portion of the deposition apparatus 100 of FIG. 1 in a closed position of the removable closing plate (see e.g. removable closing plate 270 in FIG. 3A). Processing units 170, for example coating sources, can be arranged facing the processing drum 130. In the rear of the processing unit 170, e.g. a deposition unit, which is facing away from the processing drum 130, a shielding 260 can be arranged to prevent deposition of coating material on surrounding surfaces. A further shielding 260 can be attached to the second process separating wall portion 220. Shielding 260 prevents elements within the deposition apparatus, such as the second process separating wall portion 220, from being coated with layer deposition material from a deposition source or can reduce coating of the element in the deposition apparatus. In the compartments or processing sections 180′, 180″, processing units 170 can be arranged for the deposition of material onto a flexible substrate 105. The processing units 170 can be e.g. sputtering cathodes, rotatable cathodes having target tubes, evaporators, or CVD sources like e.g. PECVD sources, micro-wave antennas, or even etching tools.

The first process separating wall portion 210 can be provided with reinforcing element 200 having apertures 250. Behind the reinforcing element 200 and aperture 250, a vacuum pump 160 can be arranged for evacuating, e.g. selectively evacuating, processing section 180″. The vacuum pump 160 can be attached to the housing wall of processing chamber 110. The adjacent compartment with corresponding processing section 180′ can be evacuated by a further vacuum pump which is not depicted in FIGS. 2A and 2B. The processing sections can each be evacuated with one or more vacuum pumps. Increasing the number of vacuum pumps increases the pumping capacity for evacuating the processing sections. An increased pumping capacity may be beneficial for deposition apparatuses with increased coating width for broader substrates.

According to embodiments described herein, a process separating wall can be provided between two compartments or adjacent processing sections of the processing region, respectively. As shown in FIG. 2A, these sections can be processing sections 180′ and 180″. The process separating wall is provided by a first process separating wall portion 210 and a second process separating wall portion 220. The first process separating wall portion 210 and the second process separating wall portion 220 can be engaged with each other, for example in a closed position of the removable closing plate, e.g. in operation of the apparatus.

Two adjacent sections of the processing region are separated from each other by a seal. The seal can be provided between the first process separating wall portion and the second process separating wall portion. Further, a seal can be provided between the first process separating wall portion and the housing wall of the apparatus 100. The housing wall of the apparatus 100 can be the housing wall of processing chamber 110. The housing wall of the apparatus 100 can include the lateral walls and a rear wall.

FIG. 2A shows a cross-section wherein a seal 230 is provided between the first and the second process separating wall portions and a seal 230 is provided between the first process separating wall portion 210 and the housing wall of processing chamber 110. Seal 230 can be an inflatable seal or gasket which can be activated. Activating the seal is performed by pressurizing the inflatable seal or gasket. The inflatable seal or gasket can be inflated with pressurized air or process gases. It can be sufficient to connect the inner tube of the inflatable seal or gasket to ambient air. The atmospheric pressure, i.e. the pressure difference of atmospheric pressure to the process pressure inside the evacuated deposition apparatus may be sufficient to pressurize the inflatable seal or gasket. By activating the seal or gasket, a remaining distance between the first process separating wall portion and the housing walls of the vacuum deposition apparatus can be closed. For deactivating the seal, the inflatable seal or gasket is depressurized.

The portions of the seal shown in FIG. 2A can be portions of one seal, such as an inflatable seal, which at least partially surround the first process separating wall portion. The inflatable seal can be pressurized in order to seal the engagement portions between the first process separating wall portion and the second process separating wall portion and/or the first process separating wall portion and the housing of the apparatus. Beneficially, the seal can surround at least a portion of the first process separating wall portion 210. Accordingly, upon inflating the inflatable seal, i.e. upon pressurizing the inflatable seal, the engagement portions between the first process separating wall portion and the second process separating wall portion and the first process separating wall portion and the housing of the apparatus are sealed.

Providing a seal between the first process separating wall portion and the housing wall of the apparatus can include a seal between the first process separating wall portion and, both, the lateral housing walls and the rear wall of the processing chamber 110. As shown in FIG. 3B, the first process separating wall portion 210 can be provided with seals 230 along the two longitudinal sides. The front face or front side of the first process separating wall portion 210 can be provided with a further seal 230. The seals 230 can be provided as an at least partially circumferential inflatable gasket encompassing the first process separating wall portion. The seal 230 can be provided as one single inflatable seal which at least partially encompasses the first process separating wall portion along the two longitudinal sides and the front side. One end of the inflatable seal 230 can be attached to a vacuum feedthrough device 340 to conduct the inflatable seal through the closing plate to atmospheric side. The vacuum feedthrough device 340 can be attached to the removable closing plate 270.

As described above, the first process separating wall portion is attached to the closing plate. The second process separating wall portion is attached to the rear wall of the vacuum chamber or a housing of the vacuum chamber. Accordingly, the second process separating wall portion remains within the chamber even if the closing plate of the vacuum chamber is in an open position.

Referring back to FIG. 2A it is shown that opposite the processing drum 130 a second process separating wall portion 220 can be arranged. The second process separating wall portion 220 can be attached to the housing and/or the rear wall of deposition apparatus 100. The second separating wall portion can be provided to include a T-shaped portion. The first side of the T-shaped second process separating wall portion 220 can be oriented parallel to the processing drum 130. The curvatures of the T-shaped second process separating wall portion 220 and the processing drum 130 can be adapted to each other such that the curvatures define a slit or gap 240. The curvature of the T-shaped second process separating wall portion 220 can provide a concave surface. The curvature of the processing drum can provide a convex surface. The curvatures of the T-shaped second process separating wall portion 220 and the processing drum 130 can be adapted such that the curvatures have a constant distance. The distance between processing drum 130 and the second process separating wall portion 220 defines a slit or gap 240. The slit or gap 240 can be configured to provide a gas separation factor between adjacent processing sections of 1:50, particularly of 1:70, more particularly of 1:100 or even better. For achieving such a gas separation factor, the width of gap 240 can be adjusted to 4 mm or below, particularly to 0.5 mm to 3 mm, more particularly to about 2 mm.

The first side of the T-shaped second process separating wall portion 220 can be oriented parallel to the processing drum 130. The second side of the T-shaped second process separating wall portion 220 can be aligned in a radial direction respective the axis of rotation of the processing drum. The second side of the T-shaped second process separating wall portion 220 can end with a web or rib facing radially away from processing drum 130. The end of the web or rib can be provided to include a sealing surface. The sealing surface can have a shape which is adapted to interact with the seal provided at the first process separation surface. This shape can have a U-shaped cross-section. The U-shaped cross-section can be a milled groove or gutter, an elongated furrow or recess such as e.g. a notch. The ends of both, the first and second process separating wall portions 210, 220 can face each other. The U-shaped end of the second process separating wall portion 220 and the end of the first process separating wall portion 210 provided with a seal or gasket can engage with each other like e.g. tongue and groove.

FIG. 2A further shows a first process separating wall portion 210 according to embodiments described herein. The first process separating wall portion 210 can be arranged within the space between the second process separating wall portion 220 and the housing wall of processing chamber 110. The first process separating wall portion 210 can be arranged with the longitudinal axis of the first process separating wall portion parallel to the axis of rotation of processing drum 130. The first process separating wall portion 210 can be provided as a straight or flat plate. According to an alternative embodiment, the first process separating wall portion 210 can be provided as a bended or curved plate having an axis of bending parallel to the axis of rotation of the processing drum 130. By giving a shape to the cross section of the first process separating wall portion, the interaction of the engaged first and second process separation wall portions can be simplified. The shape of the cross section can be adapted to the position of the process separating wall relative to the processing drum. The azimuthal position of the process separating wall relative to the processing drum can be described in polar coordinates. If the azimuthal angle is e.g. 0° or 90° for a horizontal position, the first process separating wall portion can be a straight or flat plate. The same applies if the azimuthal angle is 180°, or 270° for a vertical position. If the position is different from the azimuthal angles 0°, 90°, 180° or 270°, it can be beneficial to adapt the cross section of the first process separating wall portion. The first end which is interacting with the second process separating wall portion can be aligned in a radial direction respective the axis of rotation of the processing drum. The second end which is facing the housing wall of the processing chamber 110 can be angled to a horizontal direction.

In a closed position of the removable closing plate, the first and second process separating wall portions 210, 220 jointly provide a process separating wall 190 dividing the processing region into adjacent processing sections 180′, 180″. With pressurized gaskets or seals 230, the first and second process separating wall portions 210, 220 jointly provide a process separating wall 190 forming a tight seal between adjacent compartments or processing sections 180′, 180″. The processes to be performed inside the compartments can be vacuum treatment processes or coating processes. The environment atmospheres inside the compartments can have a low pressure below e.g. 10⁻¹ mbar, particularly below 10⁻² mbar, more particularly below 10⁻³ mbar or even lower. Even if in adjacent compartments different, not identical process pressure levels are provided, the resulting pressure differences are in the order of magnitude as mentioned above.

FIGS. 2A and 2B show two alternative embodiments how to connect a reinforcing element 200 and a first process separating wall portion 210. As shown in FIG. 2A, two reinforcing elements 200 can be attached to the first process separating wall portion 210. A first reinforcing element is attached to the upper side of the first process separating wall portion. A second reinforcing element is attached to the bottom side of the first process separating wall portion. The seal 230 of the first process separating wall portion 210 is facing the lateral housing wall of processing chamber 110. Alternatively as shown in FIG. 2B, a single reinforcing element 200 can be attached to the first process separating wall portion 210. The first process separating wall portion 210 ends at the lateral surface of reinforcing element 200. A separate sealing element 235 with a seal 230 can be provided between the reinforcing element 200 and the housing wall of processing chamber 110. The separate sealing element 235 can include a sealing support. The sealing support can be provided with a U-shaped cross-section with the open side of the U facing the housing wall of processing chamber 110. The U-shaped cross-section can be a groove or gutter, an elongated furrow or recess such as e.g. a notch. This furrow or recess can be provided with a seal 230 such as an inflatable seal or inflatable gasket. The separate sealing element 235 including the seal 230 can be arranged in extension of the first process separating wall portion 210. Additionally or alternatively, the separate sealing element 235 can have a vertical offset. FIG. 2B shows both, the sealing element 235 and the sealing element 235′ having a vertical offset.

FIG. 3A shows a 3-dimensional view of a portion of the deposition apparatus including a removable closing plate 270 according to embodiments described herein. The removable closing plate 270 can be attached to a rack to ensure a safe movement. The removable closing plate 270 with the rack can be put on rails 310 for moving the removable closing from a closed position to an open position. The removable closing plate 270 can be provided with a sealing surface surrounding the removable closing plate at outer edges of the removable closing plate. In a closed position of the removable closing plate 270, this circumferential sealing surface provides a vacuum tight seal when the removable closing plate is pressed against sealing rings attached to the housing of processing chamber 110. The removable closing plate 270 is shown in an open position removed from apparatus 100. The removable closing plate 270 can include processing units 170, first process separating wall portions 210, seals 230 and reinforcing elements 200 and further components used for operating a vacuum deposition apparatus. The structure shown in FIG. 3A can be moved on rails 310 out of the housing of the deposition apparatus in an open position. In the open position, several components attached to the removable closing plate are accessible for maintenance. These components can be processing units 170, first process separating wall portions 210 and/or further components attached to the removable closing plate.

The removable closing plate 270 is provided with openings for providing processing units 170. The openings can be closed by flanges in a vacuum tight manner. A flange for closing an opening can be adapted to the number of processing units 170 which is to be provided in a processing section 180. The flanges can be adapted to the number and/or kind of processing units 170. An appropriate flange for one processing unit may be used. Alternatively, another flange for two processing units may be used as shown in FIG. 3A. A flange can further be adapted to the kind of processing unit 170, i.e. to the process to be conducted in a certain compartment or processing section. A flange can be adapted for the use of PVD processes like sputtering, for the use of microwave CVD deposition processes or RF CVD deposition processes as well as for etching processes. It may be possible to provide universally usable flanges which are configured to support different kinds of processing units. It is to be understood that the processes to be conducted in a deposition apparatus described herein can be layer deposition processes as well as etching processes and/or thermal treatment processes. Etching processes can be a beneficial pre- or after treatment of the substrate and/or the already deposited layers. Several processing units 170 such as deposition sources can be attached to the removable closing plate 270. The number of depicted processing units 170 is exemplarily. The embodiments described herein are not restricted to the shown number of processing units. If no process is planned in a certain compartment, the respective opening in removable closing plate 270 can be closed by a blank flange. By providing different flanges and/or different types of processing units, the deposition apparatus can be used flexibly for different processing applications.

According to a further embodiment which can be combined with other embodiments described herein, a second removable closing plate can be provided at the opposite side to the removable closing plate 270 to close the housing of the deposition apparatus on the opposite side. The second removable closing plate is not depicted in the figures. According to this embodiment, the removable closing plate 270 includes the first process separating wall portions 210. The second removable closing plate includes flanges for closing the openings. Alternatively, the second removable closing plate can be configured to close all openings as one common flange. The processing units can be attached to the one of removable closing plates. The first separation wall portions can be attached to the other one of the removable closing plates. The removable closing plate 270 comprising the first process separating wall portions 210 and the reinforcing elements 200 can be removed from the processing chamber 110 to a first side. The second removable closing plate comprising the processing units 170 can be removed from the processing chamber to a second side.

As shown in FIG. 3A, the first process separating wall portions 210 can be attached to removable closing plate 270. The end sections of the first process separating wall portions 210 are configured to engage with the second process separating wall portions 220 which are not depicted in FIG. 3A. The end sections of the first process separating wall portions 210 can be configured to point in a direction which runs radially to the processing drum. As described above, the shape of the first process separating wall portions 210 is not restricted to a special shape. The first process separating wall portions 210 can be provided as plates having a curvature along their longitudinal direction. The shape perpendicular to the longitudinal direction of the first process separating wall portions 210 can be adapted to the mechanical purposes or requirements inside the vacuum chamber.

FIG. 3A further illustrates that a first process separating wall portion 210 can be attached to a reinforcing element 200. A reinforcing element 200 can be configured to connect two or more first process separating wall portions 210. The reinforcing element 200 can be attached to the removable closing plate 270. The reinforcing element and the one or more first process separating wall portions can be mechanically attached together as a structure. The structure can provide a stiff or inflexible construction. The stiff or inflexible construction can be attached to the removable closing plate. The stiff or inflexible construction can be attached to the removable closing plate 270 as cantilever construction. The embodiment illustrated in FIG. 3A shows two reinforcing elements 200 having a horizontal and a vertical portion. The corner between the vertical parts of the reinforcing elements 200 and the horizontal parts can be further reinforced by stiffeners 280. By mechanical attachments as, e.g. bolting, riveting or welding, the structure including the first process separating wall portions 210 and the reinforcing elements 200 can provide a stiff or inflexible construction.

The stiff or inflexible construction comprising a first process separating wall portion 210 and a reinforcing element 200 can be designed such that the stiff or inflexible construction is strong enough to further support the second end of processing unit 170. As described above, a first end of a processing unit 170 can be supported by a flange which can be attached to the removable closing plate 270. A bearing can be attached to the flange for supporting the first end of processing unit 170. As shown in FIG. 3A, the processing units 170 can be cantilever mounted processing units. The processing units can be e.g. rotatable cathodes, microwave antennas or other elongated deposition sources. With increasing length of a cantilever mounted processing unit, increasing flexural forces act upon the bearing attached to the first end of processing unit 170. Processing units 170 with increased length can be provided with a bearing at the second end. The second end of a processing unit is facing away from closing plate 270. For absorbing the flexural forces of a longer cantilever mounted processing unit 170, the second end can be supported by a bearing, e.g. an outboard bearing 330. Such outboard bearing 330 of a processing unit 170 can be supported by a bearing plate 300 which is depicted in FIG. 3A with contour of the bearing plate.

The reinforcing elements 200 can be provided with several apertures 250 for evacuating the respective compartments with the corresponding processing sections. The number of apertures 250 is not restricted to that of FIG. 3A; the number of apertures can be related to the length of the deposition apparatus 100 and/or the number of vacuum pumps intended for the respective processing section. The apertures 250 can be provided at the lateral or vertical parts of the reinforcing elements 200 as well as at the horizontal bottom plates.

FIG. 3B shows another 3-dimensional view of the removable closing plate 270 with the attached components. The removable closing plate 270 can be attached to a rack 325 to ensure a safe movement. Removable closing plate 270 with the rack 325 can be put on rails 310 for moving the removable closing plate from a closed position to an open position. A media supply for operation of the deposition apparatus and/or the processing units can be placed in a cable carrier 320 as shown in the rear of the removable closing plate. FIG. 3B further shows a vacuum feedthrough device 340 for the supply of pressurized air or gas for the inflatable seals or inflatable gaskets. A further seal 230′ arranged at least partially in a circle interacts with the circular shaped gas separation unit 350 of FIG. 4 which is described more detailed below. Radially outward running portions of further seals interact with the second process separation wall portions in the closed position of the removable closing plate. The radially arranged seals and/or the further seal 230′ arranged at least partially in a circle can be provided as sealing lips. A sealing lip provides a tight sealing by pressing a sealing surface upon the sealing lip. The radially arranged seals and/or the further seal 230′ arranged at least partially in a circle can be provided as inflatable seals or inflatable gaskets.

As described above, the shape of the reinforcing elements 200 is not restricted to the L-shaped plates as shown in FIG. 3A. According to the embodiment illustrated in FIG. 3B, the reinforcing element 200 can be provided as a plate arranged between two neighboring first process separating wall portions 210. One first process separating wall portion and a further first process separating wall portion can mechanically be connected with a reinforcing element. The structure comprising first process separating wall portions 210 and reinforcing elements 200 can mechanically be attached together in order to create a stiff or inflexible construction.

According to a further embodiment which can be combined with other embodiments described herein, the structure comprising first process separating wall portions 210 and reinforcing elements 200 can further mechanically be stiffen or reinforced by an additional reinforcement plate 290. The additional reinforcement plate 290 can be attached to the front sides of the first process separating wall portions 210 and a reinforcing element 200. The front side of this structure faces away from removable closing plate 270. The additional reinforcement plate 290 can be a solid plate. The additional reinforcement plate 290 can be a plate with apertures or can be a frame-like element as shown in FIG. 3B.

The additional reinforcement plate 290 can be provided with a bearing plate 300 for supporting bearings. The bearing plate 300 can be a part of the additional reinforcement plate 290. The bearing plate 300 can be a section of the additional reinforcement plate 290. The bearing plate 300 can be attached to the additional reinforcement plate 290 as a separate element. According to yet a further embodiment which can be combined with other embodiments, the bearing plate 300 can be attached directly to a first process separating wall portion 210 as a separate element. The bearing plate configured as a separate element can be unilaterally attached to a first process separating wall portion 210 as a single piece. The single piece bearing plate can be cantilever mounted, fixed upright or attached in a hanging position.

FIG. 4 illustrates a 3-D view of the processing chamber 110 in an open position of the deposition apparatus. In the open position of removable closing plate 270, the winding system and particularly the processing drum 130 remain in the housing of processing chamber 110. Further, the second process separating wall portions 220 remain in the housing of processing chamber 110. In the open position, the processing units and the first process separating wall portions are located outside the housing of processing chamber 110. Removing the processing units and the first process separating wall portions provides space for maintenance access for an operator.

A winding section of processing chamber 110 can be arranged in a section above the processing drum 130. The winding system can comprise spreader rollers, guiding rollers or deflection rollers. According to an embodiment, the rigidly attached last process separating walls 195 upstream the processing region and/or downstream the processing region can be arranged above the processing drum 130. The last process separating walls 195 upstream the processing region and/or downstream the processing region can be provided as single pieces rigidly attached to the housing and/or to the rear wall. The last process separating walls upstream the processing region and/or downstream the processing region can be provided as single pieces further rigidly attached to a frame-like portion of the processing chamber housing. The frame-like portion of the processing chamber housing comes into contact with the removable closing plate in the closed position. The rigidly attached last process separating walls provided as single pieces provide the possibility for operators to perform maintenance in the winding section of processing chamber 110.

The bearings of the rollers facing away from the rear wall 390 can be supported by a support plate 360. The support plate 360 can be attached to the frame-like housing wall of the processing chamber 110 arranged opposite to the rear wall 390. Below the winding system, a coating roller or processing drum 130 can be arranged. The bearing of processing drum 130 that faces away from rear wall 390 can be supported by a support unit 380. Support unit 380 and support plate 360 can be mechanically connected by connecting piece 370. Support unit 380 can further be supported by the process separating wall 190′ underneath the processing drum 130. The bearings of the rollers and the coating drum facing the rear wall 390 can be attached to the rear wall. In light of the above, both ends of the rollers, and particularly of the processing drum, can be supported by the floor or ground of the housing, particularly by utilizing the processing separating wall 190′.

According to an alternative embodiment of the disclosure described herein, support plate 360, connecting piece 370, and support unit 380 can be provided as one single piece. According to yet a further embodiment, an elongated support unit 380 can be attached to and supported by the bottom wall of processing chamber 110. The process separating wall 190′ can be attached to this elongated support unit 380. Between the elongated support unit 380 and the process separating wall 190′, a gas tight sealing can be provided.

The processing drum of the roll-to-roll deposition apparatus rotates around an axis for transporting a flexible substrate. In substrate transport direction, the gas separation is provided by the slit or gap between the second process separating wall portions and the coating drum. Since the processing drum is rotating and the chamber walls of the deposition apparatus facing the front sides of the processing drum are static, a further gas separation unit can be provided at both ends of the processing drum. The further gas separation units prevent a gas flow at the front sides of the processing drum between adjacent processing sections. The further gas separation units provide a seal between the rotating processing drum and the static closing wall and the rear wall, respectively. The further gas separation unit can be provided as a circular shaped gas separation unit 350 at both ends of the processing drum. The circular shaped gas separation unit 350 provided at the one end of processing drum 130 can be attached to the rear wall 390. The circular shaped gas separation unit 350 provided at the opposite end of processing drum 130 can be attached to the process separating wall 190′ underneath the processing drum 130. The circular shaped gas separation unit 350 provided at the opposite end can further be attached to the last process separating wall 195 upstream the processing region and/or the last process separating wall 195 downstream the processing region. The circular shaped gas separation unit 350 includes sheets having a curvature. The curvature of the sheets can be adapted to the curvature of processing drum 130. The circular shaped gas separation units 350 can be arranged in a distance close to processing drum 130. The distance defines a slit or gap to provide a separation of process gas atmospheres between the adjacent processing sections. The slit or gap can be configured to provide a gas separation factor between adjacent processing sections of 1:100 or even better. For achieving such a gas separation factor, the width of gap can be adjusted to 1 mm to 3 mm. The circular shaped gas separation units 350 can be attached to or connected with the second process separating wall portions 220.

The edges of the circular shaped gas separation unit 350 facing the removable closing plate 270 in the closed position provide a gas tight sealing in contact with the further seal 230′ arranged at least partially in a circle as shown in FIG. 3B. In the closed position of removable closing plate 270, the edges of the circular shaped gas separation unit 350 come into contact with the further seal 230′. Further, the edges of the rip-like parts of the second process separating wall portions come into contact with the radially outward running seals as shown in FIG. 3B. The circular shaped gas separation units can be arranged statically. The rip-like parts of the second process separating wall portions can be arranged statically. The statically arranged components provide a sealing in contact with the removable closing plate 270 in the closed position. The circular shaped gas separation units 350 face the processing drum with a slit or gap in between. The circular shaped gas separation units 350 provide a dynamic separation of processing gas atmospheres of adjacent processing sections.

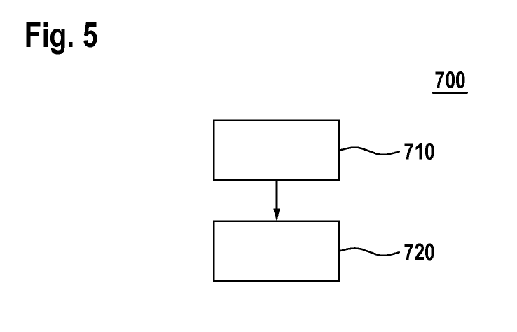

FIG. 5 shows a flowchart of a method 700 for providing a gas tight process separating wall between adjacent processing sections in a vacuum chamber according to embodiments described herein. The gas tight process separating wall may be arranged in a deposition apparatus for manufacturing of flexible substrates coated with thin films or layers or stacks of layers comprising metals or dielectric compounds thereof

According to an aspect of the present disclosure, the method 700 includes in block 710 moving a first process separating wall portion into a vacuum chamber by closing the vacuum chamber with a removable closing plate. According to embodiments described herein, the method 700 further includes a block 720 activating a gas tight seal between the first process separating wall portion, a second process separating wall portion and a housing of the vacuum chamber. According to an embodiment, activating the gas tight seal is performed by pressurizing an inflatable gasket.

While the foregoing is directed to embodiments of the disclosure, other and further embodiments of the disclosure may be devised without departing from the basic scope thereof, and the scope thereof is determined by the claims that follow.

1. An apparatus for processing a thin film on a substrate, comprising:
a vacuum chamber comprising a housing, a rear wall and a removable closing plate;
a processing drum being arranged between the rear wall and the removable closing plate inside the vacuum chamber, the processing drum being at least partially surrounded by a processing region;
a first process separating wall portion attached to the removable closing plate; and
a second process separating wall portion attached to the housing or the rear wall, wherein in a closed position of the removable closing plate, the first process separating wall portion and the second process separating wall portion jointly provide a process separating wall dividing the processing region into adjacent processing sections.

2. The apparatus of claim 1, wherein the first process separating wall portion comprises a seal.

3. The apparatus according to claim 2, wherein the seal provides a seal between the first process separating wall portion and the second process separating wall portion.

4. The apparatus according to claim 1, wherein the second process separating wall portion is kept in a preselected distance to the processing drum, wherein the distance of the second process separating wall portion to the processing drum defines a gap.

5. The apparatus according to claim 4, wherein the gap is configured to provide a gas separation factor between adjacent processing sections of 1:100 or better.

6. The apparatus according to claim 1, further comprising:
at least one processing unit wherein the at least one processing unit is attached to the removable closing plate.

7. The apparatus according to claim 1, further comprising:
at least one guide roller wherein ends of the at least one guide roller and the processing drum that face toward the removable closing plate are attached by bearings to a support plate connected to the housing.

8. The apparatus according to claim 1, wherein the housing of the vacuum chamber has a top wall having a recess wherein at least one vacuum pump is provided within the recess.

9. The apparatus according to any claim 1, further comprising a further first process separating wall portion, wherein the first process separating wall portion and the further first process separating wall portion are mechanically connected with a reinforcing element.

10. The apparatus according to claim 1, wherein the first process separating wall portion is provided with a bearing plate supporting an end of the at least one processing unit.

11. The apparatus according to claim 1, further comprising:
a further process separating wall provided as a single piece rigidly attached to the housing or to the rear wall.

12. The apparatus according to claim 15, wherein the further process separating wall is one of a last process separating wall upstream the processing region, another last process separating wall downstream the processing region, or a process separation wall supporting the processing drum.

13. The apparatus according to claim 1, wherein in an open position, the removable closing plate and the first process separating wall portion together are displaced.

14. An apparatus for processing a thin film on a substrate, comprising:
a vacuum chamber comprising a housing, a rear wall and a removable closing plate;
a processing drum being arranged between the rear wall and the removable closing plate inside the vacuum chamber, the processing drum being at least partially surrounded by a processing region;
one or more first process separating wall portions attached to the removable closing plate;
one or more second process separating wall portions attached to the housing or the rear wall; and
at least one processing unit attached to the removable closing plate, wherein two neighboring first process separating wall portions are mechanically connected with a reinforcing element, and wherein the one or more first process separating wall portions and the one or more second process separating wall portions jointly provide one or more process separating walls dividing the processing region into at least two adjacent processing sections.

15. A method for providing a gas tight process separating wall between adjacent processing sections in a vacuum chamber, comprising:
moving a first process separating wall portion into a vacuum chamber by closing the vacuum chamber with a removable closing plate; and
activating a gas tight seal between the first process separating wall portion and a second process separating wall portion.

16. A method according to claim 15, wherein activating the gas tight seal is performed by pressurizing an inflatable gasket.

17. The apparatus of claim 1, wherein the first process separating wall portion comprises an inflatable seal.

18. The apparatus according to claim 2, wherein the seal provides a seal between the first process separating wall portion and the second process separating wall portion, and the first process separating wall portion and the housing.

19. The apparatus according to claim 2, further comprising:
at least one processing unit wherein the at least one processing unit is attached to the removable closing plate.

20. The apparatus according to claim 17, further comprising:
at least one processing unit wherein the at least one processing unit is attached to the removable closing plate.
